(19) United States
(12) Patent Application Publication
(10) Pub. No.: US 2007/0210334 A1
(43) Pub. Date: Sep. 13, 2007

(54) Phase change memory device and method of fabricating the same

(76) Inventors: Young-Soo Lim, Cheongju-si (KR); Yong-Sun Ko, Suwon-si (KR); Hyuk-Jin Kwon, Seongnam-si (KR); Jae-Seung Hwang, Suwon-si (KR)

Correspondence Address: HARNESS, DICKEY & PIERCE, P.L.C., P.O. BOX 8910, RESTON, VA, 20195, US

(21) Appl. No.: 11/698,155

(22) Filed: Jan. 26, 2007

(30) Foreign Application Priority Data
Jan. 27, 2006 (KR) 10-2006-0008919

(51) Int. Cl. H01L 31/00

(52) U.S. Cl. 257/200

(57) ABSTRACT

Example embodiments relate to a semiconductor memory device and a method of fabricating the same. Other example embodiments relate to a phase change memory device and a method of fabricating the same. There are provided a phase change memory device and a method of fabricating the same for improving or maximizing a production yield. The method comprises: after first removing a first hard mask layer used to form a contact pad electrically connected to a semiconductor substrate, forming a lower electrode to be electrically connected to the contact pad through a first contact hole in a first interlayer insulating layer formed on the contact pad and to have a thickness equal or similar to a thickness of the first interlayer insulating layer; and forming a phase change layer and an upper electrode on the lower electrode. Because change of the resistance value of the lower electrode is reduced or prevented, which has been caused due to a non-uniform thickness of a conventional first hard mask layer, a production yield may be improved.

### PRIORITY STATEMENT

This application claims priority under 35 USC § 119 to Korean Patent Application No. 10-2006-0008919, filed Jan. 27, 2006, in the Korean Intellectual Property Office (KIPO), the entire contents of which are herein incorporated by reference.

### BACKGROUND

1. Technical Field

Example embodiments relate to a semiconductor memory device and a method of fabricating the same. Other example embodiments relate to a phase change memory device and a method of fabricating the same.

2. Discussion of Related Art

Semiconductor memory devices used for storing data are generally divided into volatile memory devices and non-volatile memory devices. In the volatile memory device (e.g., dynamic random access memory (DRAM) and/or static random access memory (SRAM)), the data input/output operation may be faster, but stored data may be lost when power is cut. The DRAM may need a periodical refresh operation and a higher electrical charge-storage capability. Many efforts have been made to increase a capacitance of the DRAM device. For example, a method of increasing a capacitance by increasing the surface area of a lower electrode of a capacitor may be used. The integration density of the DRAM device may decrease as the surface area of the lower electrode increases.

In the non-volatile memory device (e.g., a NAND and/or NOR type flash memory) based on an electrically erasable programmable read only memory (EEPROM), stored data may be maintained even though the power is cut. The non-volatile memory device may have a gate pattern formed by stacking a gate insulating layer, a floating gate, a dielectric layer and a control gate on a semiconductor substrate. To record or erase data in the non-volatile memory device, a method of tunneling an electrical charge through the gate insulating layer may be used and an operation voltage higher than a source voltage may be required. The flash memory device may need a voltage boosting circuit to form a required voltage for recording/erasing data and it may increase the design rule.

According to the development of technologies in the field of information and communication and the rapid popularization of information media, for example, computers, the demand has gradually increased for a semiconductor memory device capable of higher speed operation, with higher capacity memory-storage capability. A semiconductor device has been developed, combining the advantages of a volatile memory device (e.g., the DRAM) and those of a non-volatile memory device (e.g., the flash memory). The conventional semiconductor device may have lower power consumption upon driving and improved data retention capability and read/write operation. The conventional semiconductor device may be a ferroelectric random access memory (FRAM), a magnetic random access memory (MRAM), a phase change random access memory (PRAM) and/or a nano floating gate memory (NFGM).

Among semiconductor memory devices, the PRAM (i.e., a phase change memory device) may have a simpler structure, higher integration density at relatively inexpensive costs and relatively high-speed operation capability. In the phase change memory device, data may be stored using a resistance difference caused by a change in the crystal structure of a phase change material layer. A chalcogenide compound (GST: Ge—Sb—Te), including germanium (Ge), antimony (Sb) and tellurium (Te), may be used as the phase change material. The crystal structure of the phase change material may vary depending on the intensity of a supplied current and the time spent supplying the current. The crystal structure of the phase change material may become amorphous or crystalline depending on given conditions. The phase change material in the amorphous state may have a higher specific resistance compared to the phase change material in the crystalline state.

Logic information stored in the unit cell of the phase change memory device may be determined by detecting the change of the currents flowing through the phase change material. In order to change the crystal structure of the phase change material used in the conventional phase change memory device from an amorphous state to a crystalline state, or from a crystalline state to an amorphous state, heat may be used. After the phase change material layer is heated to a temperature of about the melting point for a relatively short time and the phase change material layer is quenched, the heated portion of the phase change material layer may be in an amorphous state. After the phase change material layer is crystallized by maintaining a crystallization temperature below about the melting point for a relatively long time and the phase change material layer is cooled, the heated portion of the phase change material layer may be in a crystalline state. For example, after GST is heated to a temperature around its melting point (about 610° C.) for a relatively short time (about 1˜10 ns) and the GST is quenched, the GST may be in an amorphous state. After the GST is heated to a temperature around its crystallization temperature (about 450° C.) for a relatively long time (30˜50 ns) and the GST is cooled, the GST may be crystallized.

The heat supplied for the phase change of the phase change material may be represented as Joule heat. Joule heat may be generated using the current passing through the phase change material and may cause a higher temperature in the phase change material. Because the resistance of the phase change material is higher when the phase change material is in the amorphous state, it may be easier to generate the heat required to change to the crystalline state. Because the resistance of the phase change material is lower when the phase change material is in the crystalline state, it may be more difficult to generate the heat required to change to the amorphous state. The phase change material may be auxiliarily heated at a lower electrode (for example, a heating electrode) in contact with the phase change material, for example, a bottom electrode contact (BEC) to facilitate the heating of the phase change material, under conditions capable of more easily phase-changing the phase change material.

The conventional phase change memory device may include an access transistor and the phase change material. The access transistors may be electrically connected to word lines and bit lines, which may be formed above the access transistors to cross with each other, so as to store information to the phase change material or read the information from the phase change material. The phase change material may be formed on the access transistor and may be formed between an upper electrode and a lower electrode in contact with the two electrodes. The upper electrode may be connected to a ground electrode and the lower electrode may be connected to a contact plug and a contact pad, which are electrically connected to the access transistor. As described above, the lower electrode may be formed to have a more uniform resistance to assist the heating for the phase change of the phase change material. The lower electrode may be designed to have an ohmic contact resistance at the interface between the lower electrode and the phase change material and a length between the phase change material and the contact pad may be more uniformly maintained.

For example, the contact pad connected to the lower electrode may be electrically connected to a contact plug formed on a source/drain impurity region at one side of the access transistor. The contact pad may be formed at the same level as the bit line, which is electrically connected to another contact plug formed on a source/drain impurity region at the other side of the access transistor opposite to the contact pad.

The bit line and the contact pad may be patterned by a dry etch process using a photoresist layer and a hard mask layer as an etch mask layer scaling-down a semiconductor line width. For example, the hard mask layer may be first patterned using the photoresist layer and after the photoresist layer is removed, the contact pad may be formed using the hard mask layer as an etch mask layer. Because the hard mask layer may be partially lost while a conductive metal layer of the contact pad is removed, the thickness of the hard mask layer may be reduced. The hard mask layer may include a silicon nitride layer and may also be used as an etch stop layer during a dry etch process on a first interlayer insulating layer. The first interlayer insulating layer may be formed on the contact plug to selectively expose the contact plug.

When the contact pad is formed, if the hard mask layer is etched irregularly on the surface of the wafer, the contact pad may be more easily damaged during the formation of a first contact hole in a subsequent etch process of a first interlayer insulating layer due to the irregularly-etched hard mask layer, so as to cause under-cuts. Because the length of the lower electrode formed inside the first contact hole becomes non-uniform, the resistance of the lower electrode may be different, thereby deteriorating a production yield.

Although the irregularly-etched hard mask layer is removed using a chemical mechanical polishing process, because it is more difficult to detect the etch stop point of the hard mask layer, the chemical mechanical polishing process may not be performed uniformly, thereby resulting in deterioration of a production yield.

### SUMMARY

Example embodiments relate to a semiconductor memory device and a method of fabricating the same. Other example embodiments relate to a phase change memory device and a method of fabricating the same.

Example embodiments provide a phase change memory device and a method of fabricating the same, for improving or maximizing a production yield by forming a lower electrode. The lower electrode may be formed inside a first contact hole on a contact pad to have a more uniform resistance value even though a first hard mask layer may not be uniformly etched during patterning of the contact pad. Example embodiments provide a phase change memory device and a method of fabricating the same, for improving a production yield by more uniformly removing a hard mask layer on a contact pad.

Example embodiments provide a method of fabricating a phase change memory device. A contact pad and a first hard mask layer may be formed and the first hard mask layer may be removed exposing the contact pad. A lower electrode may be formed to be electrically connected to the contact pad through a first contact hole in a first interlayer insulating layer formed on the contact pad and a phase change layer may be formed and an upper electrode may be formed on the lower electrode.

The lower electrode may have a thickness equal or similar to a thickness of the first interlayer insulating layer. The first hard mask layer may be removed by performing a wet etch process using an etchant having a higher etch selectivity with respect to the first hard mask layer than the contact pad. The first contact hole may be formed by forming a second hard mask layer on the first interlayer insulating layer formed on the contact pad, to selectively expose the first interlayer insulating layer on the contact pad and performing a dry etch process using the second hard mask layer as an etch mask.

After forming a contact plug to be electrically connected to a semiconductor substrate by a second contact hole formed in a second interlayer insulating layer on the semiconductor substrate, the contact pad and the first hard mask layer may be formed to be electrically connected to the contact plug. A third interlayer insulating layer may be formed around the contact pad and the first hard mask layer. After removing the first hard mask layer, the first interlayer insulating layer may be formed on the semiconductor substrate in which the contact pad is exposed and the first interlayer insulating layer may be removed from the contact pad, so as to form a third contact hole exposing the contact pad. A metal layer may be formed on the semiconductor substrate, so as to fill the third contact hole. After forming the phase change layer and the upper electrode, the lower electrode may be formed by planarizing the semiconductor substrate to expose the first interlayer insulating layer. The first hard mask layer may include a silicon nitride layer.

Each of the second interlayer insulating layer, the third interlayer insulating layer and the first interlayer insulating layer may include a silicon oxide layer formed using at least one process selected from a thermal oxidation process (e.g., high temperature oxide (HTO), middle temperature oxide (MTO), middle temperature oxide nitride oxide (MTON₂O) and/or any other suitable process) and/or a chemical vapor deposition process (e.g., high density plasma (HDP), TEOS, USG, SOG and/or any other suitable process). The contact plug may be connected to source/drain impurity regions at both sides of a gate stack of a transistor formed on the semiconductor substrate. The forming of the third interlayer insulating layer may include forming a third interlayer insulating layer with a given thickness on the first hard mask layer and the second interlayer insulating layer and planarizing the semiconductor substrate to expose the first hard mask layer. The forming of the third contact hole may include stacking a first interlayer insulating layer and a second hard mask layer on the semiconductor substrate in which the contact pad may be exposed and removing the second hard mask layer and the first interlayer insulating layer formed on the contact pad.

The first interlayer insulating layer and the second hard mask layer may be formed in-situ inside one process chamber where a chemical vapor deposition process is performed. Removing the second hard mask layer may include planarizing the semiconductor substrate to expose the first interlayer insulating layer after forming the conductive metal layer filling the third contact hole during the formation of the lower electrode. The lower electrode may include at least one selected from titanium (Ti), titanium nitride (TiN) and titanium oxynitride (TiON) using a chemical vapor deposition process. The phase change layer may include at least one material selected from Ge, Sb, Te, Se, Bi, Pb, Sn, As, S, Si, P, O and a mixture or alloy thereof. The phase change layer may be in an amorphous state at the initial deposition time and at a temperature of about 100° C. to about 300° C. The upper electrode may be formed at a given temperature or less so as to not be changed out of its initial state.

Other example embodiments provide a phase change memory device. A first interlayer insulating layer may be formed on a semiconductor substrate and a contact plug may be electrically connected to the semiconductor substrate, through a second contact hole formed in the second interlayer insulating layer. A contact pad may be formed on the contact plug and a third interlayer insulating layer may be formed on the second interlayer insulating layer around the contact pad. A third interlayer insulating layer may be formed on the contact pad and the third interlayer insulating layer and a lower electrode may be electrically connected to the contact pad through the third contact hole formed in the first interlayer insulating layer to expose the contact pad. A phase change layer and an upper electrode may be stacked on the lower electrode and the first interlayer insulating layer and a fourth interlayer insulating layer may be formed on the first interlayer insulating layer around the phase change layer and the upper electrode.

### BRIEF DESCRIPTION OF THE DRAWINGS

Example embodiments will be more clearly understood from the following detailed description taken in conjunction with the accompanying drawings. FIGS. 1-5L represent non-limiting, example embodiments as described herein.

FIG. 1 is a diagram illustrating a memory cell array of a phase change memory device according to example embodiments;

FIG. 2 is a circuit diagram illustrating an equivalent circuit of a memory cell array according to example embodiments;

FIG. 3 is a graph illustrating changes of crystal structures of a phase change material layer employed in a phase change memory device in accordance with temperature and time according to example embodiments;

FIG. 4 is a diagram illustrating a phase change memory device according to example embodiments; and

FIGS. 5A through 5L are diagrams illustrating a method of fabricating a phase change memory device in accordance with processing sequences according to example embodiments.

### DETAILED DESCRIPTION OF EXAMPLE EMBODIMENTS

Various example embodiments are described more fully hereinafter with reference to the accompanying drawings, in which example embodiments are shown. Example embodiments may, however, be embodied in many different forms and should not be construed as limited to the example embodiments set forth herein. Rather, these embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. A first element, component, region, layer or section discussed below could be termed a second element, component, region, layer or section without departing from the teachings of the example embodiments.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. The exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the example embodiments. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-section illustrations that are schematic illustrations of idealized, example embodiments (and intermediate structures). As such, variations from the shapes of the illustrations as a result, for example, of manufacturing techniques and/or tolerances, are to be expected. Example embodiments should not be construed as limited to the particular shapes of regions illustrated herein but are to include deviations in shapes that result, for example, from manufacturing. For example, an implanted region illustrated as a rectangle will, typically, may have rounded or curved features and/or a gradient of implant concentration at its edges rather than a binary change from implanted to non-implanted region. Likewise, a buried region formed by implantation may result in some implantation in the region between the buried region and the surface through which the implantation takes place. The regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments relate to a semiconductor memory device and a method of fabricating the same. Other example embodiments relate to a phase change memory device and a method of fabricating the same.

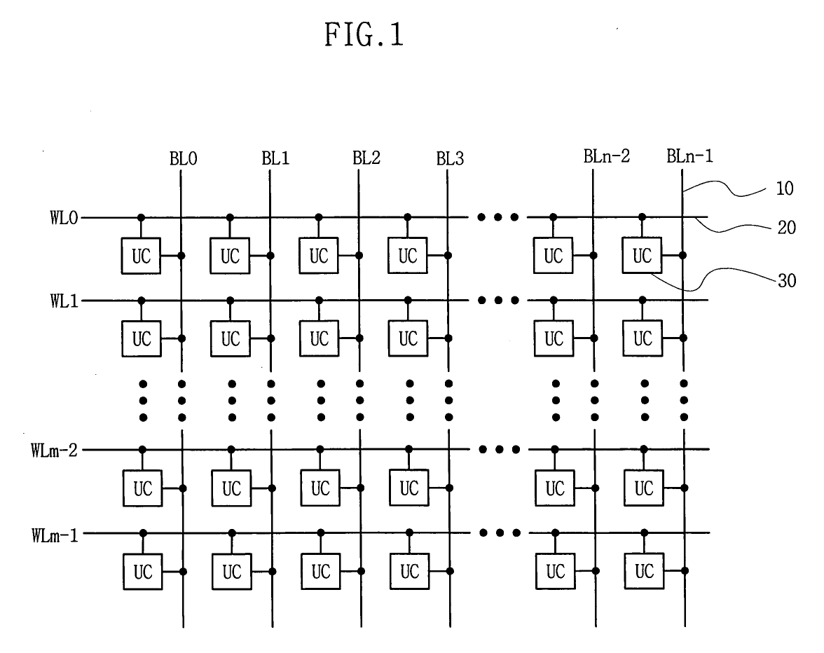

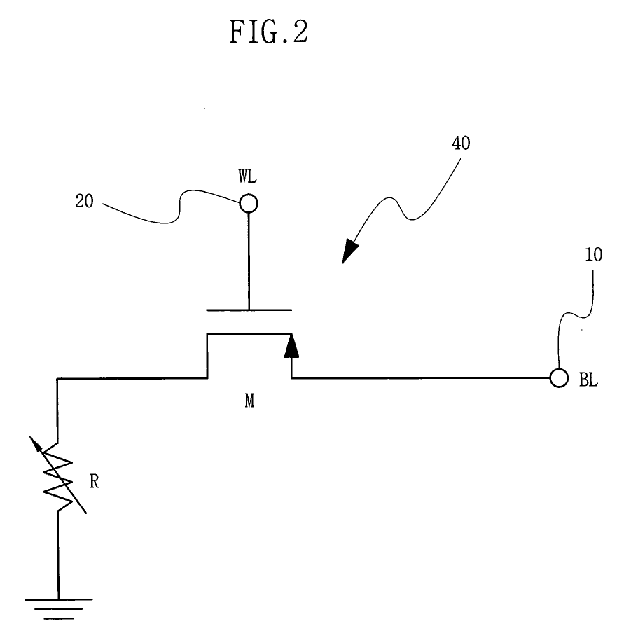

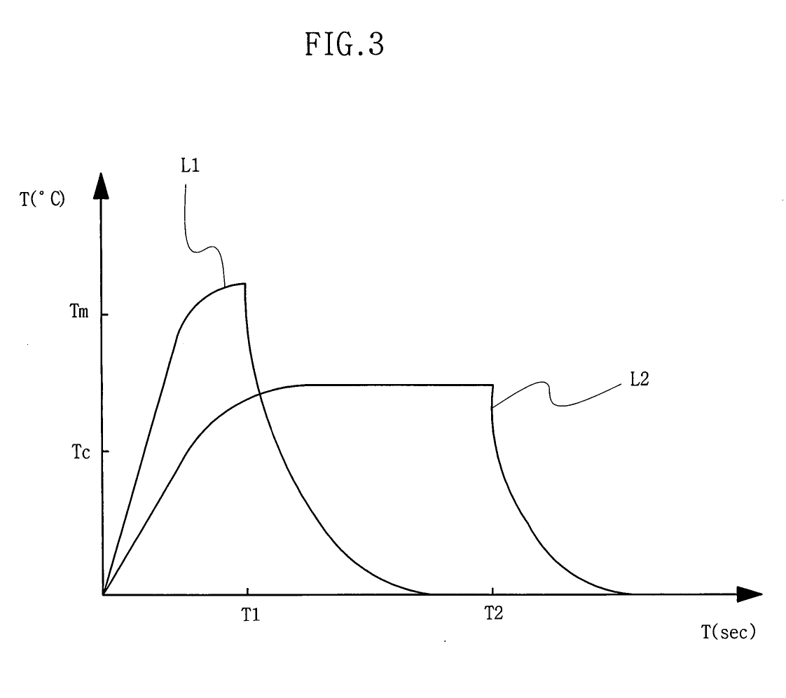

FIG. 1 is a diagram illustrating a memory cell array of a phase change memory device according to example embodiments, FIG. 2 is a circuit diagram illustrating an equivalent circuit of a memory cell array according to example embodiments and FIG. 3 is a graph illustrating changes of crystal structures of a phase change material layer employed in a phase change memory device in accordance with temperature and time according to example embodiments.

As illustrated in FIGS. 1 through 3, the cell array of the phase change memory device may include a plurality of bit lines 10 aligned along one direction, a plurality of word lines 20 aligned along one direction perpendicular to the bit lines 10, a plurality of phase change memory cells 30, each cell being formed at the position where the word line 20 and the bit line 10 cross with each other, and a plurality of access transistors 40 respectively disposed adjacent to the phase change memory cells 30 and recording and/or reading information to/from the phase change memory cells 30.

One access transistor 40 and one phase change memory cell 30 may be formed at each position where the word line 20 and the bit line 10 cross with each other. A gate electrode of the access transistor 40 may be electrically connected to the word line 20. The bit line 10 may be electrically connected to a drain region of the access transistor 40. N word lines 20 (WL0˜WLn—1) and m bit lines 10 (BL0˜BLm−1) may be formed to have a matrix structure and phase change memory cells 30 (unit cell: UC) may be respectively formed at the positions where n word lines 20 (WL0˜WLn−1) and m bit lines 10 (BL0˜BLm−1) may cross each other, with the number of n×m. Sensor amplifiers (not shown) may be formed in a peripheral region of the cell array with each connected to the end of each bit line 10, in order to read the information stored in the phase change memory cells 30, via the signals applied to the bit lines 10. Hereinafter, a split type of a cell array will be explained, in which one bit line 10 may be connected to a common drain region and a phase change memory cell 30 may be formed at a source region of each of a plurality of access transistors 40 formed at both ends of the common drain region, in order to increase an integration density of a semiconductor device.

The phase change memory cell 30 may be formed to correspond to a variable resistance R having a given resistance value when a given current is applied by an access signal applied to the access transistor 40. For example, the phase change memory cell 30 may be connected to a source region formed at both ends and/or one end of the common drain region connected to the bit line 10 and may be connected to a ground end and/or back-bias end opposite to the source region. The phase change memory cell 30 may be composed of a programmable phase change material, which may be phase-changeable in accordance with given conditions. For example, the phase change material may be a chalcogenide compound (GST: Ge—Sb—Te) composed of germanium (Ge), antimony (Sb) and tellurium (Te). The phase change material may be heated to a relatively high temperature by Joule heat so that the phase changes. When a given current is applied to the phase change material, a Joule heat may be generated and thus, the phase change material may be heated to a relatively high temperature. The phase change material, itself, may be heated by the Joule heat in accordance with a specific resistance of the phase change material and in proportion to the current and time applied to the phase change material. For example, when a phase change material layer is heated to a temperature higher than its melting point Tm (about 610° C.) for a time T1 and quenched, the crystal structure of the phase change material layer may be changed to an amorphous state (line L1). Data ‘1’ as a program state, e.g., a RESET state, may be stored.

In the meantime, when the phase change material layer is heated to a temperature higher than its crystallization temperature Tc (about 450° C.) but lower than its melting point Tm (about 610° C.) for a time T2 longer than the time T1 and cooled more slowly, the crystal structure of the phase change material layer may be changed to a crystalline state, in which its crystal structure has a regularity (line L2). Data ‘0’ as an erase state, e.g. a SET state, may be stored. The phase change material layer with a crystalline structure may have a lower relative resistance than that of the phase change material layer having an amorphous structure. Data ‘1’ or ‘0’ may be discerned in a read operation by using a voltage difference in accordance with current flowing through the phase change material layer at a variable resistance R.

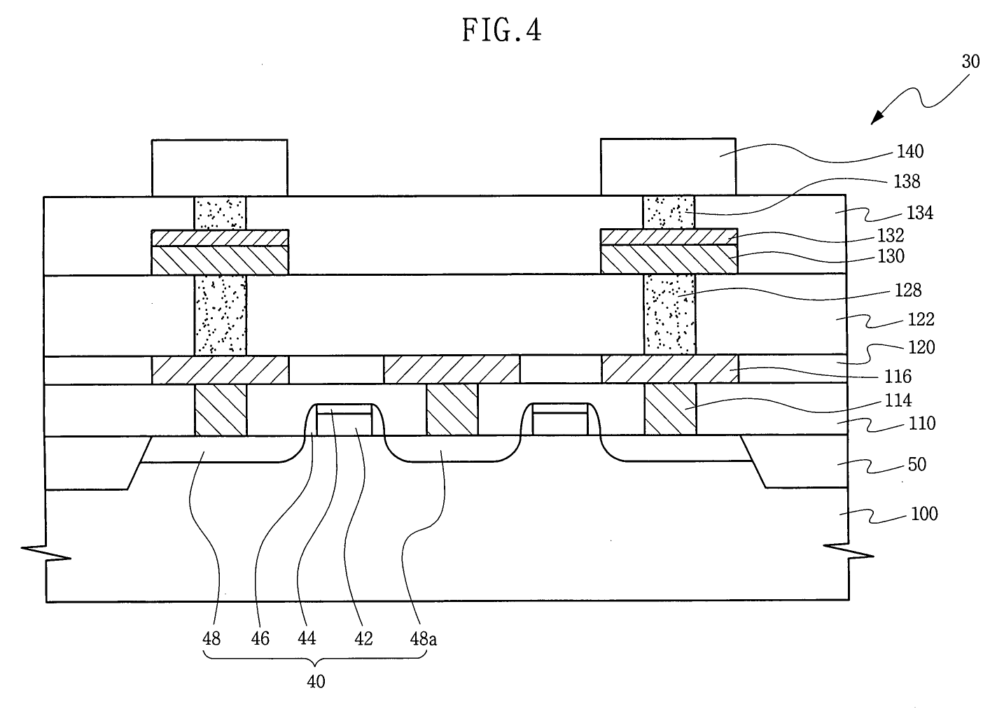

When the phase change material layer in a crystalline state having a lower relative resistance is changed to the phase change material layer having an amorphous structure, a higher current may be applied than the current applied to change the phase change material layer having an amorphous structure to the phase change material layer having a crystalline structure. While reducing the current flowing through the phase change material layer, the phase change material layer at the interface in contact with a lower electrode 128 (FIG. 4) may be auxiliarily heated under the conditions for the phase change of the phase change material layer. The additional heating of the phase change material having a crystalline structure up to a given temperature may help to decrease the viscosity of the phase change material having the crystalline structure and may facilitate changing the phase change material having the crystalline structure to the phase change material having an amorphous structure.

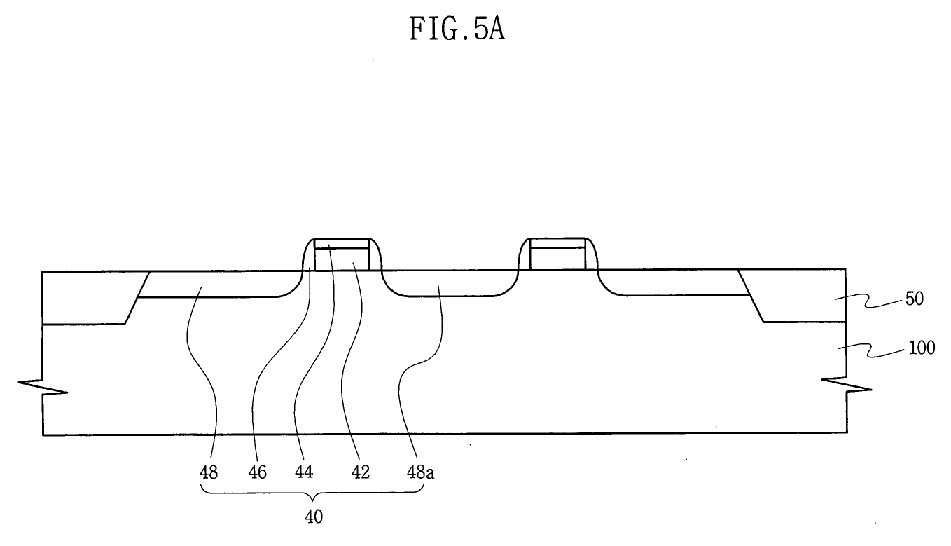

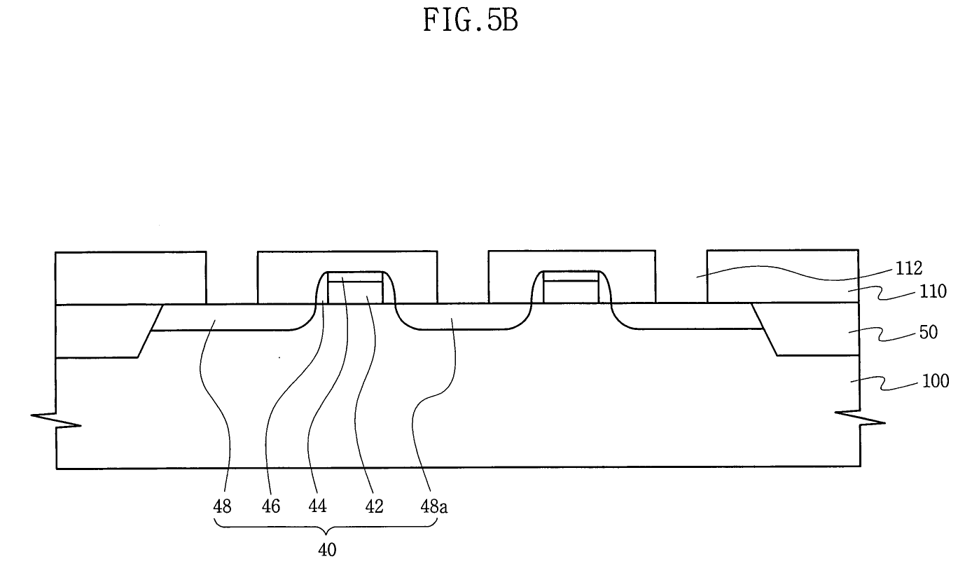

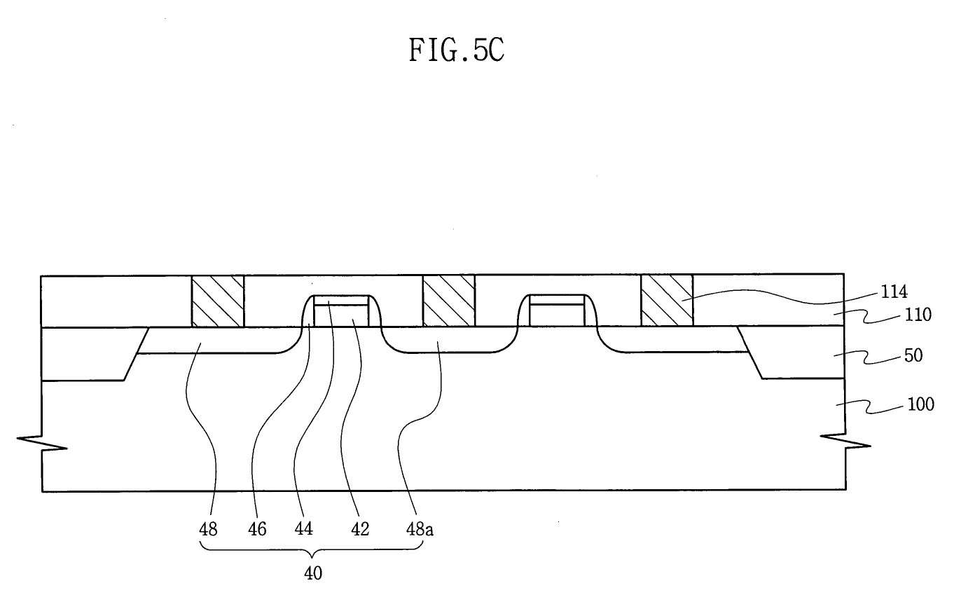

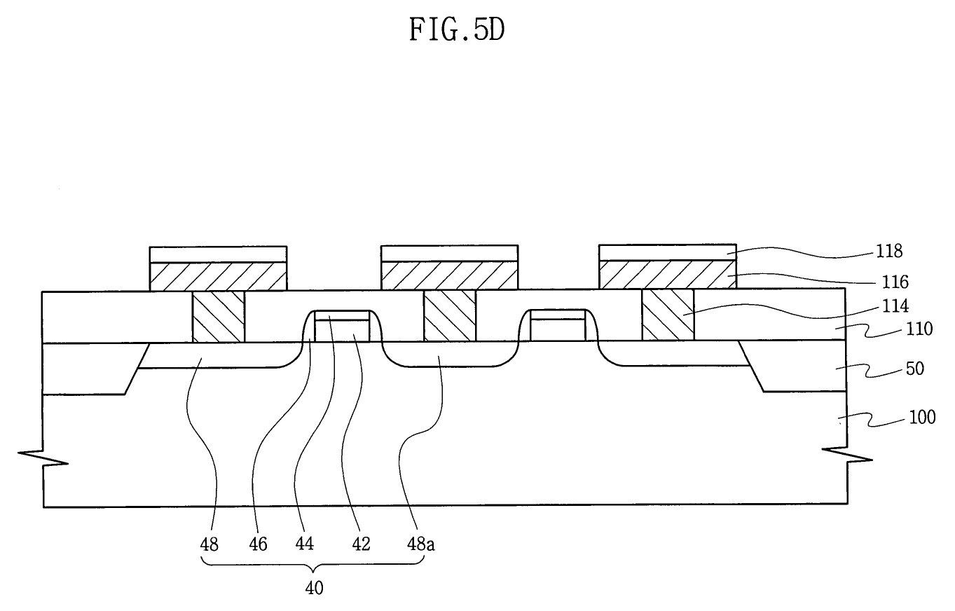

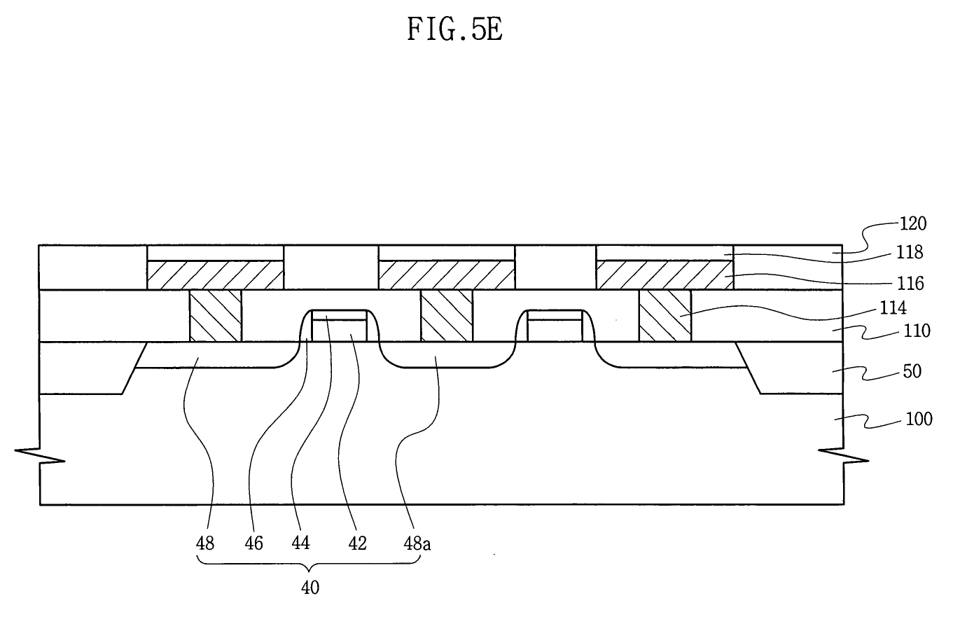

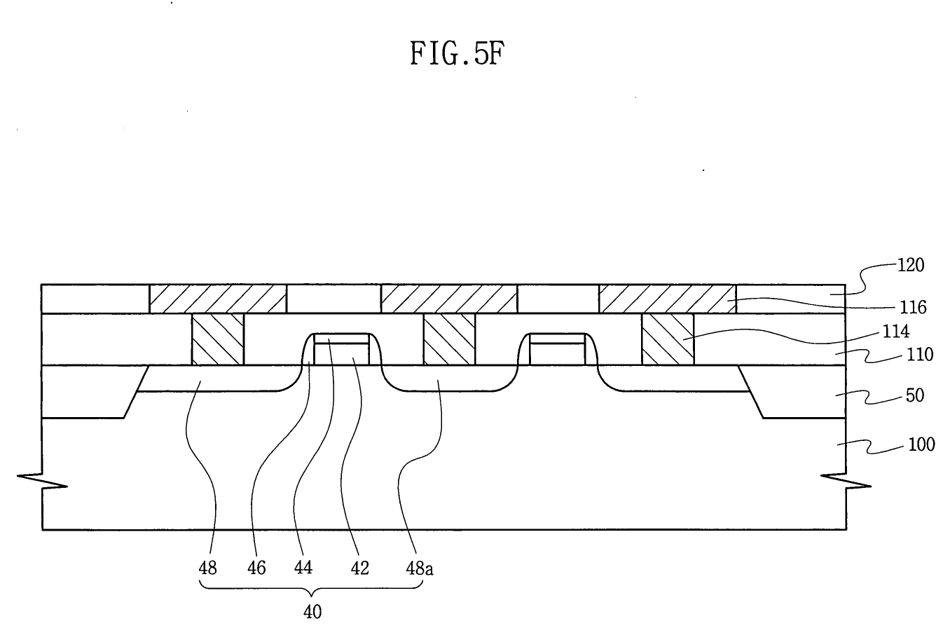

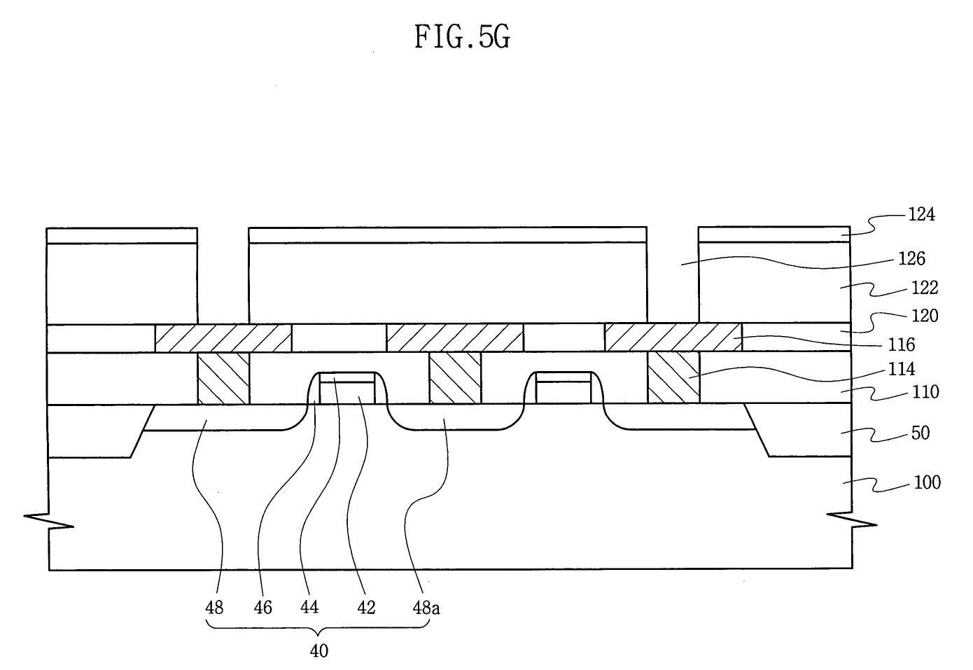

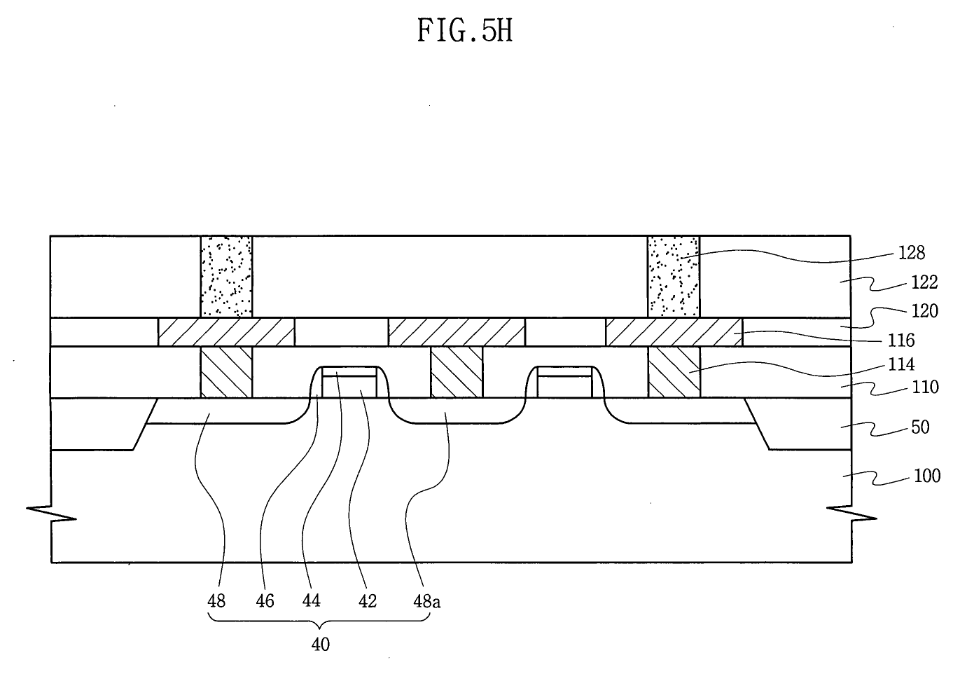

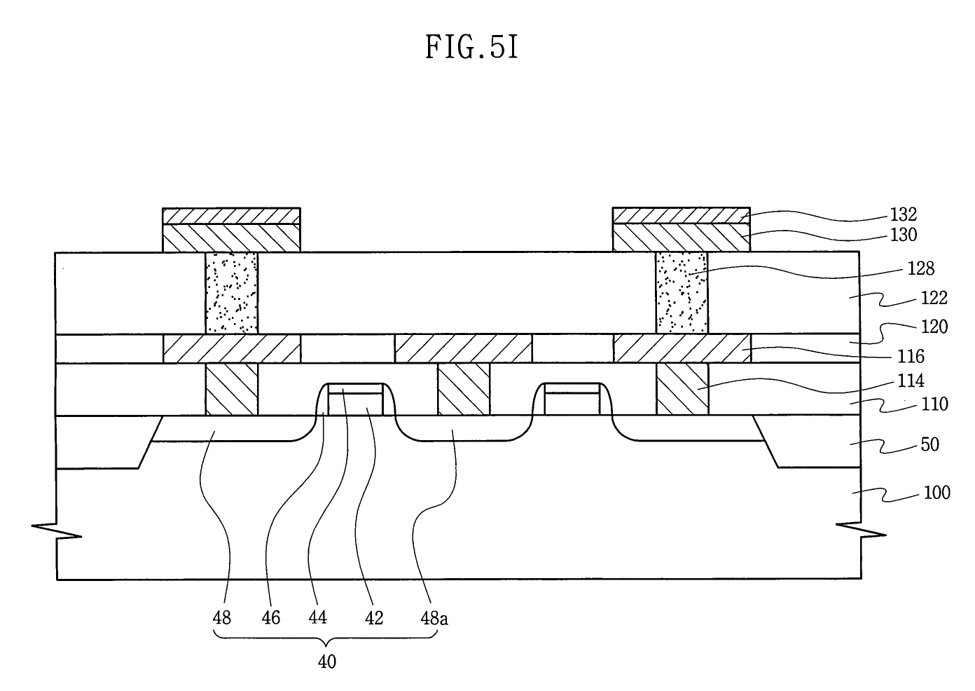

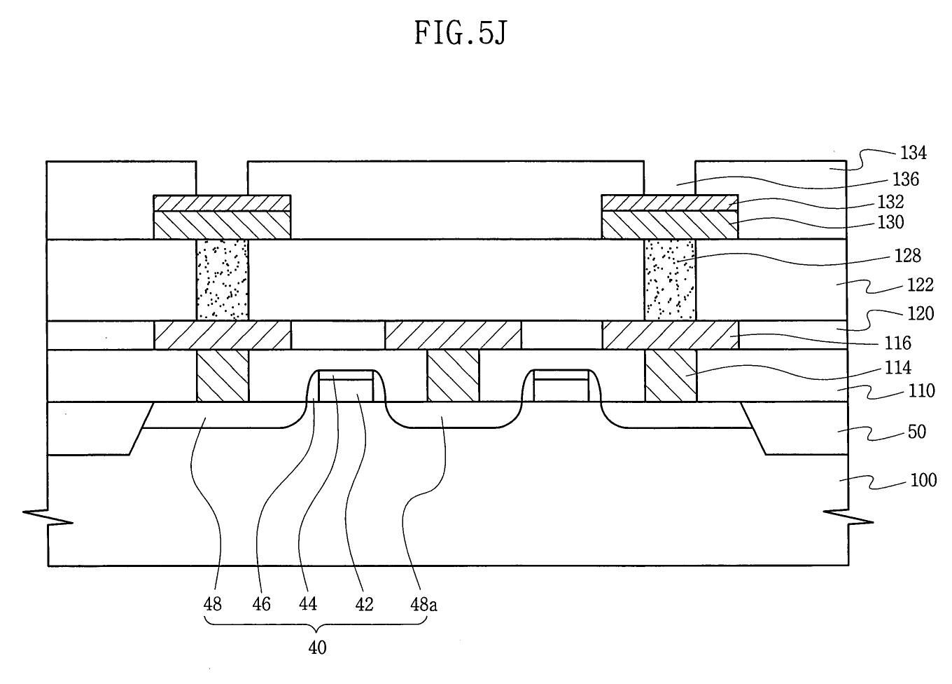

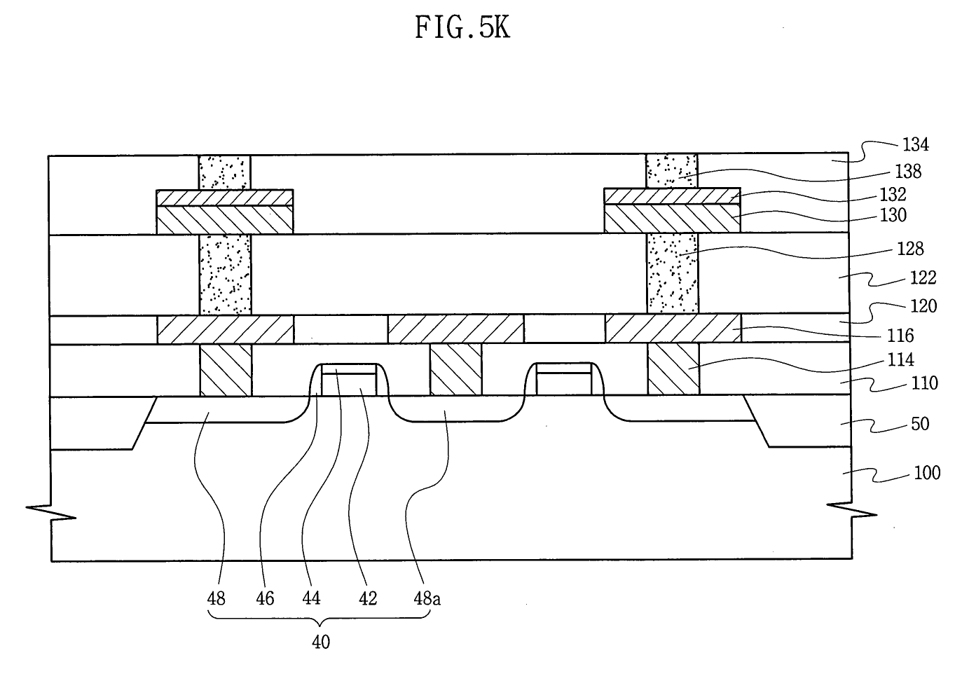

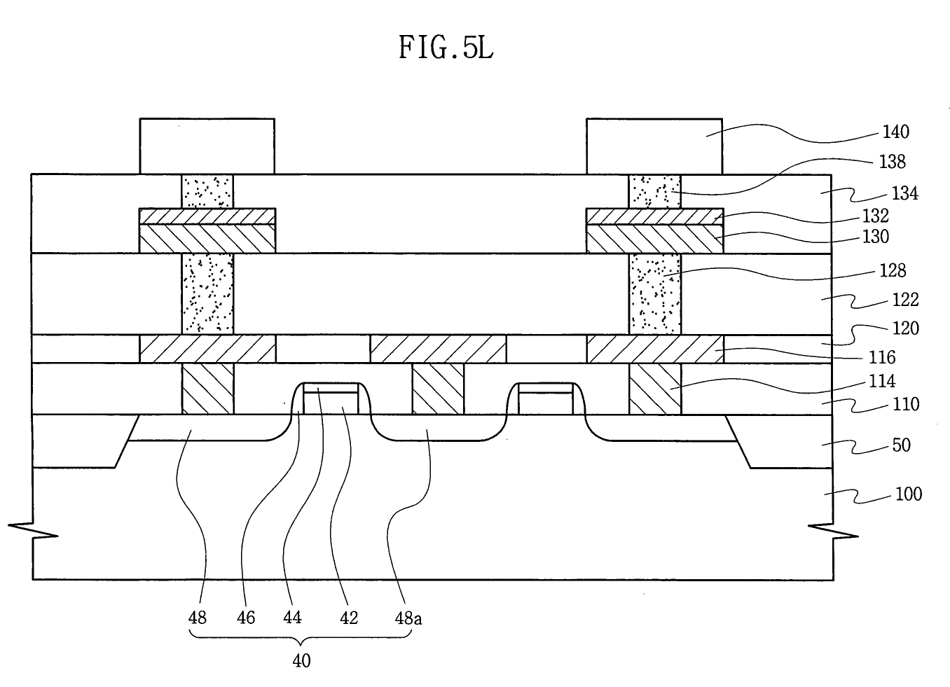

FIG. 4 is a diagram illustrating a phase change memory device according to example embodiments. As illustrated in FIG. 4, the phase change memory device may include a plurality of access transistors 40 formed in active regions defined by isolation layers 50 in a semiconductor substrate 100, a second interlayer insulating layer 110 formed on the access transistor 40 and a first contact plug 114 electrically connected to the semiconductor substrate 100 via a second contact hole (see FIG. 5B) formed in the second interlayer insulating layer 110. A contact pad 116 may be formed on the first contact plug 114 and a third interlayer insulating layer 120 may be formed around the contact pad 116 on the second interlayer insulating layer 110. A first interlayer insulating layer 122 may be formed on the contact pad 116 and the third interlayer insulating layer 120 and a lower electrode 128 may be formed in the first interlayer insulating layer 122 to be electrically connected to the contact pad 116 via a third contact hole (see FIG. 5G) that is formed to expose the contact pad 116. A phase change layer 130, an upper electrode 132 and a fourth interlayer insulating layer 134 may be formed on the phase change layer 130, the upper electrode 132 and the first interlayer insulating layer 122, which are stacked on the lower electrode 128 and the first interlayer insulating layer 122. A second contact plug 138 may be formed to be electrically connected to the upper electrode 132 via a first contact hole (see FIG. 5J) formed in the fourth interlayer insulating layer 134 and a metal line 140 formed on the second contact plug 138.

Each of the plurality of access transistors 40 may include a gate stack including a gate electrode 42 having a gate insulating layer (not shown) on the active region and a gate upper insulating layer 44 formed on the gate electrode 42. A spacer 46 may be formed on the sidewall of the gate stack and source/drain impurity regions may be formed at both sides of the spacer 46 in the active region and doped with conductive impurities. Although not shown in the drawing, the access transistor 40 may further include a channel region (not shown) below the gate stack doped with conductive impurities having a conductivity type opposite to that of the conductive impurities of the source/drain impurity regions 48. Lightly doped drain regions may be formed below the spacer 46 and doped with a lower dose than that of the source/drain impurity regions 48, while extending from the source/drain impurity regions 48 to the channel region. For example, the conductive impurities may be group III impurities (e.g., boron (B)) and/or group V impurities (e.g., phosphorus (P) and/or arsenic (As)).

The first contact plug 114 may be electrically connected to the source/drain impurity regions of the access transistor 40 via the second contact hole (see FIG. 5B) of the second interlayer insulating layer 110. The first contact plug 114 and the source/drain impurity regions may be connected to create an ohmic contact resistance. For example, the first contact plug 114 may be composed of polysilicon doped with conductive impurities and/or a metal layer including at least one selected from the group consisting of tungsten silicide, aluminum silicide, aluminum (Al), tantalum (Ta) and/or copper (Cu).

The contact pad 116 may be formed by patterning the metal layer formed on the first contact plug 114 and the second interlayer insulating layer 110. For example, the contact pad 116 may be formed of a metal layer including at least one selected from the group consisting of tungsten (W), aluminum (Al) and/or tantalum (Ta). The contact pad 116 may be formed on the first contact plug 114 and the second interlayer insulating layer may be formed 110 before the third interlayer insulating layer 120. For example, in a split structure of a cell array, the contact pad 116, which is electrically connected to the common drain impurity region 48a between neighboring access transistors 40 via the first contact plug 114, may be formed of the bit line 10. The bit line 10 may be more easily formed as the contact pad 116 by patterning the conductive metal layer formed on the first contact plug 114 and the second interlayer insulating layer 110, compared to the first contact plug 114 formed by filling the second contact hole (see FIG. 5B) of the second interlayer insulating layer 110. With interconnections (e.g., the bit lines 10) decreasing in line width and being more delicate, the contact pad 116 may be more easily formed by patterning the metal layer in such a manner that the first hard mask layer 118 (e.g., a silicon nitride layer) may be formed on the metal layer. The first hard mask layer 118 may be patterned using the photoresist layer and the metal layer may be patterned using the first hard mask layer 118 as an etch mask, rather than by patterning the metal layer using a photoresist layer as an etch mask. The first hard mask layer 118 may not be etched uniformly on the semiconductor substrate 100 depending on distances and widths of the exposed portions during the formation of the contact pad 116 and the bit line 10. For example, while a distance between the contact pads 116 at both sides of the bit line 10 is narrower, because a distance between the contact pads 116 at both sides of the isolation layer 50 is wider, the first hard mask layer 118 may be etched irregularly during the dry etch process using the first hard mask layer 118 as an etch mask.

The third interlayer insulating layer 120 may be formed on the entire surface of the semiconductor substrate 100 where the contact pad 116, the bit line 10 and the first hard mask layer 118 may be formed. The semiconductor substrate 100 may be planarized using the first hard mask layer 118 as an etch stop layer. The first hard mask layer 118 may be removed using a wet etch process.

According to example embodiments, the phase change memory device 30 may remove the first hard mask layer 118 having the non-uniform thickness on the contact pad 116. A production yield may be improved by removing the first hard mask layer 118 formed on the contact pad 116 before the lower electrode 128 is formed. Resistance of the lower electrode 128 may not vary during a subsequent process due to the hard mask layer being etched with a more uniform thickness during the formation of the contact pad 116.

The first interlayer insulating layer 122 may be formed with a thickness defining a length of the lower electrode 128. The first interlayer insulating layer 122 may be formed on the contact pad 116 and the third interlayer insulating layer 120. A third contact hole (see FIG. 5G) may be formed in the first interlayer insulating layer 122, so as to expose the contact pad 116. A metal layer may be formed to fill the inside of the third contact hole and the metal layer may be removed to expose the first interlayer insulating layer 122. The semiconductor substrate 100 may be planarized so as to complete the lower electrode 128.

As described above, the lower electrode 128 may allow a given current to flow through the phase change material layer with the lower electrode 128 electrically connected to the contact pad 116. The lower electrode 128 may heat the phase change material layer by the given current within the lower electrode 128 in contact with the phase change material layer. A resistance value of the lower electrode 128 may be set to contribute to the phase change of the phase change material layer from a crystalline state to an amorphous state more than the phase change of the phase change material layer from an amorphous state to a crystalline state. For example, resistance value of the lower electrode 128 may be set lower than that of the phase change material layer in an amorphous state and higher than that of the phase change material layer in a crystalline state.

The lower electrode 128 may be set to have a constant resistance value, in order to heat the phase change material layer up to a given temperature and provide uniform conditions for the phase change of the phase change material layer. The resistance value of the lower electrode 128 may be proportional to resistivity of the metal layer forming the lower electrode 128 and a height of the lower electrode 128 and inversely proportional to the section of the lower electrode 128 corresponding to the section of the third contact hole. Resistivity of the metal layer may be determined by the metal layer forming the lower electrode 128 and the section of the third contact hole (see FIG. 5G) may be determined by the reproducibility of a patterning process. A height of the lower electrode 128 may be a length ranging from the upper surface of the contact pad 116 to the upper surface of the first interlayer insulating layer 122.

The first hard mask layer 118 on the contact pad 116 may be removed and thus, a dry etch process may be performed during the formation of the third contact hole in the first interlayer insulating layer 122 so as to expose the contact pad 116. Without the first hard mask layer 118, irregular etching of the contact pad 116 may be reduced or prevented. The lower electrode 128 may be formed to have an ohmic contact resistance between the contact pad 116 and the phase change layer 130. For example, the lower electrode 128 may be formed of a metal layer composed of at least one material selected from the group consisting of titanium (Ti), titanium nitride (TiN) and/or titanium oxynitride (TiON) and may be formed to have an ohmic contact resistance.

The phase change layer 130 may be an essential component enabling the phase change memory device 30 to have its original characteristics. The phase change layer 130 may have a crystalline state and/or an amorphous state with a different resistance value depending on Joule heat generated in accordance with the current intensity applied from the access transistor 40. For example, the phase change material forming the phase change layer 130 may be composed of one material selected from the group consisting of Ge, Sb, Te, Se, Bi, Pb, Sn, As, S, Si, P, O and/or a mixture or alloy thereof. For example, a chalcogenide compound (GST: Ge—Sb—Te) including germanium (Ge), antimony (Sb) and tellurium (Te) may be used as the phase change material. In addition to the GST, other chalcogenide compounds to be used as the phase change material may be As—Sb—Te, As—Gb—Te, As—Gb—Sb—Te, Sn—Sn—Te, In—Sn—Sn—Te, Ag—In—Sb—Te, a Group 5A element (Ta, Nb, V)—Sb—Te, a Group 5A element (Ta, Nb, V)—Sb—Se, a Group 6A element (W, Mo, Cr)—Sb—Te and/or a Group 6A element (W, Mo, Cr)—Sb—Se. The compounds may be used with nitrogen. The phase change material layer may be formed to have a thickness of about 100 Å to about 1000 Å at a temperature of about 100° C. to about 300° C.

The upper electrode 132 may be formed on the phase change layer 130 opposite to the lower electrode 128 and may be formed to flow current to the ground end and/or back-bias end. The upper electrode 132 may be formed on the phase change layer 130 to cover the upper surface of the phase change layer 130. For example, the upper electrode 132 may be composed of a conductive material including nitrogen, metal, dual layer of metal and metallic silicide, alloy, metallic oxynitride and/or conductive carbon compound. For example, the upper electrode 132 may be composed of a conductive material including a nitrogen element (e.g., TiN, TaN, WN, MoN, NbN, TiSiN, TiAlN, TiBN, ZrSiN, WSiN, WBN, ZrAlN, MoSiN, MoAlN, TaSiN and/or TaAlN) and/or a conductive material layer including any one selected from the group consisting of Ti, W, Mo, Ta, TiSi, TaSi, TiW, TiON, TiAlON, WON, TaON and/or a combination thereof.

The fourth interlayer insulating layer 134 may be formed with a given thickness on the phase change layer 130 and the upper electrode 132. The fourth interlayer insulating layer 134 may be planarized using a chemical mechanical polishing process such that the phase change layer 130 and the upper electrode 132 do not protrude therefrom. A first contact hole (see FIG. 5J) may be formed to expose the upper electrode 132. The first contact hole may be formed by forming a third hard mask layer (not shown) on the planarized fourth interlayer insulating layer 134, patterning the third hard mask layer using a photoresist layer as an etch mask and performing a dry etch process using the third hard mask layer as an etch mask, so as to remove the fourth interlayer insulating layer 134 and expose the upper electrode 132. For example, the fourth interlayer insulating layer 134 may be formed of an oxide layer (e.g., SiO₂, HTO, MTO, MTON₂O, TEOS, USG, SOG, HDP and/or the like). A protecting layer (not shown) may be further formed to cover the phase change layer 130 and the upper electrode 132, so that the oxide component of the fourth interlayer insulating layer 134 is not diffused into the phase change layer 130 and the upper electrode 132. For example, the protecting layer may be formed of a silicon nitride layer. The second contact plug 138 may be formed to fill the first contact hole and a metal line 140 may be formed on the second contact plug 138 using a typical metal-deposition process and/or a photolithography process. The second contact plug 138 may be referred to as a via contact connecting the upper electrode 132 and the metal line 140 and the metal line 140 may be connected to the ground end or back-bias end.

According to example embodiments, the phase change memory device 30 may improve a production yield by first removing the first hard mask layer 118 with a non-uniform thickness on the contact pad 116 and reducing or preventing an undercut problem caused by the non-uniform thickness of the conventional first hard mask layer 118 during the formation of the third contact hole 126 of the first interlayer insulating layer 122. A method of fabricating the phase change memory device 30 according to example embodiments structured as above will be explained as follows.

FIGS. 5A through 5L are diagrams illustrating a method of fabricating a phase change memory device in accordance with processing sequences according to example embodiments. As illustrated in FIG. 5A, in the method of fabricating a phase change memory device 30, an isolation layer 50 may be formed to isolate an active region of a semiconductor substrate 100 and an access transistor 40 may be formed on the semiconductor substrate 100 in which the active region isolated by the isolation layer 50.

The isolation layer 50 may be formed by forming a plurality of trenches with a given depth in the semiconductor substrate 100, forming a silicon oxide layer on the trench and planarizing the semiconductor substrate 100 to expose the semiconductor substrate 100, so as to isolate the active region. The access transistor 40 may be formed by forming a gate stack on a channel region of the active region selectively exposed by the isolation layer 50. The gate stack may be composed of a gate insulating layer, a gate electrode 42 and a gate upper insulating layer 44 and forming a spacer 46 at both sides of the gate stack and source/drain impurity regions at both sides of the channel region in the active region.

For example, in the formation of the gate stack, a gate insulating layer may be formed on the semiconductor substrate 100 having the isolation layer 50 and the gate electrode 42 and the gate upper insulating layer 44 may be formed on the gate insulating layer. A photoresist layer may be formed on the gate upper insulating layer 44 and then patterned. The photoresist layer may be formed to remain only on the channel region. The gate upper insulating layer 44, the gate electrode 42 and the gate insulating layer may be sequentially dry-etched, using the photoresist layer as an etch mask layer, so as to form the gate stack. After the formation of the gate stack, lightly-doped source/drain impurity regions may be formed in the active region adjacent to the channel region, using the gate upper insulating layer 44 as an ion implantation mask layer. A silicon nitride layer may be formed with a given thickness on the semiconductor substrate 100 having the lightly-doped source/drain impurity regions using a chemical vapor deposition method. The silicon nitride layer may be anisotropically etched to expose the active region of the semiconductor substrate 100, so as to form a spacer 46 on the sidewall of the gate stack. The gate insulating layer may be formed of a silicon oxide layer and/or a silicon oxynitride layer, using a rapid thermal treatment process and/or chemical vapor deposition method. The gate electrode 42 may be formed of polysilicon including conductive impurities, tungsten silicide, aluminum silicide and/or a metal layer (e.g., tungsten and/or aluminum) using a chemical vapor deposition method. The gate upper insulating layer 44 may be formed as an etch mask, instead of the photoresist layer during the dry etch process of the gate electrode 42 and the gate insulating layer. The spacer 46 may reduce or prevent exposure of the gate electrode 42 at the sidewall of the gate stack and may be used as an ion implantation mask of the source/drain impurity regions. The source/drain impurity regions 48 may be formed by implanting conductive impurities having a higher dose than that of the conductive impurities implanted into the lightly-doped source/drain impurity regions, using the gate upper insulating layer 44 and the spacer 46 as ion implantation masks. The source/drain impurity regions 48 may make contact with a first contact plug 114 in order to have an ohmic contact resistance.

As illustrated in FIG. 5B, a second interlayer insulating layer 110 may be formed with a given thickness on the semiconductor substrate 100 having the access transistor 40 and a second contact hole 112 may be formed to expose the source/drain impurity regions 48 of the access transistor 40. For example, the second interlayer insulating layer 110 may be formed to include a silicon oxide layer, using a thermal oxidation method (e.g., high temperature oxide (HTO), middle temperature oxide (MTO), middle temperature oxide nitride oxide (MTON₂O) and/or any other suitable method) and/or a chemical vapor deposition method (e.g., TEOS, USG, SOG, high density plasma oxide (HDPO) and/or any other suitable method). Depending on pressure, temperature and applied energy influencing the formation of the second interlayer insulating layer 110, the second interlayer insulating layer 110 may be deposited by an atmospheric pressure chemical vapor deposition (APCVD) process performed under atmospheric pressure, a low pressure chemical vapor deposition (LPCVD) process performed under a relatively low pressure atmosphere and/or a plasma enhanced chemical vapor deposition (PECVD) process performed under a plasma ambient.

The second interlayer insulating layer, formed with a given thickness on the semiconductor substrate by the chemical vapor deposition method, may be planarized using a chemical mechanical polishing method, so as to facilitate easy formation of the second contact hole 112. For example, the second contact hole 112 may be formed to expose the source/drain impurity regions 48 by removing the second interlayer insulating layer using a dry etch method with a photoresist layer and/or dummy hard mask layer (not shown) as an etch mask to selectively expose the second interlayer insulating layer formed on the source/drain impurity regions 48. For example, when the second interlayer insulating layer is formed of a high density plasma oxide layer with a thickness of about 2000 Å, the inner pressure of a process chamber in dry etch equipment may be maintained, for example, at 35 mT and the RF power thereof may be maintained at 400 W. The second contact hole 112 may be formed by injecting CH₂F₂ (20SCCM), O₂ (20SCCM) and Ar (180SCCM) into the process chamber and performing an etch process for about 57 seconds.

As illustrated in FIG. 5C, a conductive metal layer may be formed on the entire surface of the semiconductor substrate 100 having the second interlayer insulating layer so as to fill the first contact hole. The entire surface of the semiconductor substrate 100 may be planarized to expose the second interlayer insulating layer so as to form a first contact plug 114 electrically connected to the source/drain impurity regions 48 via the first contact hole. For example, the first contact plug 114 may be formed of a conductive metal layer including at least one selected from the group including polysilicon doped with conductive impurities, tungsten silicide, aluminum silicide, aluminum, tantalum and/or copper using a chemical vapor deposition method.

As illustrated in FIG. 5D, a conductive metal layer may be formed with a given thickness on the semiconductor substrate 100 having the first contact plug 114 and a first hard mask layer 118 may be formed to selectively cover only the conductive metal layer on the first contact plug 114. A dry etch process may be performed, using the first hard mask layer 118 as an etch mask, to remove the conductive metal layer forming a contact pad 116. The contact pad 116 may be formed using a physical deposition method (e.g., sputtering method) and/or a chemical vapor deposition method. The contact pad 116 may be formed of a pure metal layer (e.g., tungsten and/or aluminum) in order to reduce an ohmic contact resistance when electrically connected to a lower electrode 128 formed later. The contact pad 116 may be formed of a bit line 10 electrically connected by the first contact plug 114 formed between the plurality of access transistors 40. In order to form a uniform line width of the bit line 10, a highly-flexible thin film (e.g., a photoresist layer) may not be desirable as an etch mask. The first hard mask layer 118 as a hard thin film may be formed using the photoresist layer. A dry etch process may be performed using the first hard mask layer 118 as an etch mask, thereby forming the bit line 10 and the contact pad 116 with a uniform line width. For example, the first hard mask layer 118 may be formed to include a silicon nitride layer, using a chemical vapor deposition method. The photoresist layer may be removed using an ashing process after the patterning of the first hard mask layer 118 is completed. During the dry etch process using the first hard mask layer 118 as an etch mask layer, the conductive metal layer exposed by the first hard mask layer 118 may be removed and concurrently, the first hard mask layer 118 may be removed. The first hard mask layer 118 may have a lower etch selectivity than that of the conductive metal layer with respect to an etch reaction gas for removing the conductive metal layer during the dry etch process of the conductive metal layer. The first hard mask layer 118 may be overall non-uniformly etched on the semiconductor substrate 100 in accordance with the area of the exposed section and the line width of the first hard mask layer 118 by the reaction of the etch reaction gas. For example, because the etch reaction gas flows toward an edge portion of the contact pad 116 more easily than a center portion thereof, the center portion of the contact pad 116 may be formed relatively thick and the edge portion thereof may be formed relatively thin. The first hard mask layer 118 may be thinner at the peripheral region where the contact pads 116 may be formed less densely, than at the cell region where the contact pads 116 may be formed more densely.

As illustrated in FIG. 5E, a third interlayer insulating layer 120 may be formed with a given thickness on the first hard mask layer 118 and the second interlayer insulating layer 110 and the third interlayer insulating layer 120 may be planarized to expose the first hard mask layer 118. The third interlayer insulating layer 120 may be formed with a thickness corresponding to the height of the contact pad 116 and the height of the first hard mask layer 118 formed on the contact pad 116. For example, similar to the second interlayer insulating layer 110, the third interlayer insulating layer 120 may be formed to include a silicon oxide layer, using a thermal oxidation method (e.g., high temperature oxide (HTO), middle temperature oxide (MTO), middle temperature oxide nitride oxide (MTON₂O) and/or any other suitable method) and/or a chemical vapor deposition method (e.g., TEOS, USG, SOG high density plasma (HDP) and/or any other suitable method). The third interlayer insulating layer 120 may be formed with a given step height difference on the second interlayer insulating layer 110 and the first hard mask layer 118 and may be planarized using a chemical mechanical polishing method to facilitate easier formation of a first interlayer insulating layer 122 formed later. The first hard mask layer 118 may be removed using the chemical mechanical polishing method, but the exact time when the contact pad 116 is exposed using the chemical mechanical polishing method may be more difficult to detect and the contact pad 116 may be more easily damaged by a polishing agent including strong acid chemicals used in chemical mechanical polishing equipment.

As illustrated in FIG. 5F, the first hard mask layer 118, exposed by the third interlayer insulating layer 120, may be removed. For example, the first hard mask layer 118 may be removed using a wet etch process with an etchant including phosphoric acid. The first hard mask layer 118, formed on the contact pad 116, may be removed, using a time etch process in the wet etch process. When the first hard mask layer 118 is removed, the third interlayer insulating layer 120 may also be etched. There may be a step height difference between the contact pad 116 and the third interlayer insulating layer 120. The used etchant may have a higher etch selectivity with respect to the first hard mask layer 118 than the contact pad 116. However, the etchant may have a similar etch selectivity with respect to the first hard mask layer 118 and the third interlayer insulating layer 120. The etchant may have a higher etch selectivity with respect to the first hard mask layer 118 than the third interlayer insulating layer 120, or the etchant may have a higher etch selectivity with respect to the third interlayer insulating layer 120 than the first hard mask layer 118. By performing a wet etch process using an etchant having a higher etch selectivity with respect to the first hard mask layer 118 than the contact pad 116, the first hard mask layer 118 may be removed and the contact pad 116 may be exposed by the third interlayer insulating layer 120. In the method of fabricating the phase change memory device, the first hard mask layer 118 on the contact pad 116 may be more uniformly removed by performing a wet-etch process on the first hard mask layer 118 used for the formation of the contact pad 116.

As illustrated in FIG. 5G, a first interlayer insulating layer 122 and a second hard mask layer 124 may be stacked on the entire surface of the semiconductor substrate 100 where the contact pad 116 is exposed and the second hard mask layer 124 and the first interlayer insulating layer 122 on the contact pad 116 are removed, so as to form a third contact hole 126. The first interlayer insulating layer 122 and the second hard mask layer 124 may be formed in-situ inside one process chamber where a chemical vapor deposition method is performed, or may be respectively formed in different process chambers. For example, similar to the second interlayer insulating layer 110 and the third interlayer insulating layer 120, the first interlayer insulating layer 122 may be formed to include a silicon oxide layer, using a thermal oxidation method (e.g., high temperature oxide (HTO), middle temperature oxide (MTO), middle temperature oxide nitride oxide (MTON₂O) and/or any other suitable method) and/or a chemical vapor deposition method (e.g., TEOS, USG, SOG, high density plasma (HDP) and/or any other suitable method). The second hard mask layer 124 may be formed to include the silicon nitride layer, using the chemical vapor deposition method.

Like the first hard mask layer 118, the second hard mask layer 124 may be formed by forming a photoresist layer locally exposing the second hard mask layer 124 on the contact pad 116, patterning the second hard mask layer 124 by performing a dry etch process using the photoresist layer as an etch mask and ashing the photoresist layer. A dry etch process using the second hard mask layer 124 as an etch mask may be performed to remove the first interlayer insulating layer 122 on the contact pad 116, so as to form the third contact hole 126. For example, the first interlayer insulating layer 122 may be removed using an etch reaction gas having a chemical (e.g., CH₂F₂ and/or CF₄) as a main element and the first interlayer insulating layer 122 may be removed by the etch reaction gas having a flow rate of CF₄ (80SCCM) and O₂ (20SCCM) for about 30 seconds at about 45 W of RF power.

As illustrated in FIG. 5H, the lower electrode 128 may be formed inside the third contact hole 126. The lower electrode 128 may be formed by forming a conductive metal layer on the entire surface of the semiconductor substrate 100 having the third contact hole 126 so as to fill the third contact hole 126. The lower electrode 128 may also be formed by removing the conductive metal layer to expose the first interlayer insulating layer 122 so as to planarize the semiconductor substrate 100. For example, the lower electrode 128 may be formed to include a titanium group metal layer composed of at least one selected from titanium (Ti), titanium nitride (TiN) and/or titanium oxynitride (TiON), using a chemical vapor deposition method. The lower electrode 128 may be formed to have a height or thickness corresponding to the height of the third contact hole 126 formed in the first interlayer insulating layer 122 on the contact pad 116, after the first hard mask layer 118, used to form the contact pad 116, is removed.

In the method of fabricating the phase change memory device according to example embodiments, even though the first hard mask layer 118 is irregularly etched, because the first hard mask layer 118 used in the patterning of the contact pad 116 is first removed and the third contact hole 126 exposing the contact pad 116 may be formed in the first interlayer insulating layer formed on the contact pad 116, the lower electrode 128 formed inside the third contact hole 126 on the contact pad 116 may be formed to have a uniform resistance value and a production yield may be improved or maximized. The bottom of the lower electrode 128 may be the upper surface of the contact pad 116 exposed by the first contact hole formed in the first interlayer insulating layer 122 and the upper surface of the lower electrode 128 may be in the line extending from the first interlayer insulating layer 122. The second hard mask layer 124 may be removed during the formation of the lower electrode 128. For example, the second hard mask layer 124 may not be removed so that it may be used during a subsequent process. However, because the height of the lower electrode 128 buried inside the third contact hole 126 may be non-uniform, the second hard mask layer 124 may be removed.

As illustrated in FIG. 5I, a phase change layer 130 and an upper electrode 132 may be formed on the lower electrode 128, with a node separating them from each other. The phase change layer 130 and the upper electrode 132 may be formed by stacking a phase change material and a conductive metal layer on the semiconductor substrate 100 having the lower electrode 128 and patterning the phase change material and the conductive metal layer on the lower electrode 128. For example, the phase change layer 130 may be composed of one material selected from Ge, Sb, Te, Se, Bi, Pb, Sn, As, S, Si, P, O and/or a mixture or alloy thereof. Because a phase change condition may vary in accordance with a mixture ratio of the materials, the phase change layer 130 may be formed using a chemical vapor deposition method, in which a mixture ratio of the materials may be more easily controlled. The phase change layer 130 may be formed to be in an amorphous state at the time of the initial deposition at a temperature of about 100° C. to about 300° C. The upper electrode 132 may be formed of a conductive metal layer identical or similar to that of the lower electrode 128 and may be formed using a chemical vapor deposition method and/or a physical deposition method (e.g., a sputtering method). The upper electrode 132 may be formed so as to not change the initial state of the phase change layer 130, for example, at a temperature or less that may not change the initial state of the phase change layer 130. The phase change layer 130 may be phase-changed by the current applied through the upper electrode 132 and the lower electrode 128. The phase change layer may be phase-changed to be in a crystalline state in bulk from the surface in contact with the lower electrode 128 and/or the upper electrode 132. When there exists a crystalline state at the edge portion of the phase change layer 130 far apart from the upper electrode 132 and/or the lower electrode 128, the edge portion in the crystalline state may be a leakage path for the current applied to the phase change layer 130. The edge portion in the crystalline state may be easily phase-changed by the Joule heat of the phase change layer 130 and/or the auxiliary heat of the lower electrode 128. The phase change layer 130 and the upper electrode 132 may be formed at a temperature or less that may not vary the initial state of the phase change layer 130.

As illustrated in FIG. 5J, a fourth interlayer insulating layer 134 may be formed on the phase change layer 130 and the upper electrode 132, to have a first contact hole 136 through which the upper surface of the upper electrode 132 is exposed. Like the first interlayer insulating layer 122, the fourth interlayer insulating layer 134 may be formed to include a silicon oxide layer, using a thermal oxidation method (e.g., high temperature oxide (HTO), middle temperature oxide (MTO), middle temperature oxide nitride oxide (MTON₂O) and/or any other suitable method) and/or a chemical vapor deposition method (e.g., TEOS, USG, SOG, high density plasma (HDP) and/or any other suitable method). The fourth interlayer insulating layer 134 may be formed with a given thickness on the entire surface of the semiconductor substrate 100 having the phase change layer 130 and the upper electrode 132. The fourth interlayer insulating layer 134 may be planarized using a chemical mechanical polishing method and the first contact hole 136 may be formed by performing a dry etch process using a photoresist layer as an etch mask. The first contact hole 136 may be formed just by performing the dry etch process using a photoresist layer as an etch mask, because it has a lower degree of precision than that of the third contact hole 126. When the first contact hole 136 has a critical value similar in size to that of the third contact hole 126, the first contact hole 136 may be formed by forming a third hard mask layer (not shown) on the fourth interlayer insulating layer 134 and performing a dry etch process using the third hard mask layer as an etch mask.

As illustrated in FIG. 5K, a second contact plug 138 may be formed to fill the first contact hole 136. The second contact plug 138 may be formed by forming a conductive metal layer on the fourth interlayer insulating layer 134 having the first contact hole 136, removing the conductive metal layer to expose the fourth interlayer insulating layer 134 and planarizing the entire surface of the semiconductor substrate 100. For example, the second contact plug 138 may be formed such that its contact area with the upper electrode 132 is greater than the area that the lower electrode 128 contacts the phase change layer 130. The second contact plug 138 may reduce or prevent losing current applied to the upper electrode 132, by electrically connecting with the upper electrode 132 and allowing the contact area with the upper electrode 132 to increase. The second contact plug 138 may be formed of a conductive metal layer identical or similar to that of the upper electrode 132 using a chemical vapor deposition method and/or a physical deposition method (e.g., a sputtering method) and/or may be composed of one selected from polysilicon doped with conductive impurities having improved conductivity, tungsten silicide, aluminum silicide, tungsten, aluminum and/or copper.

As illustrated in FIG. 5L, a metal line 140 may be formed on the second contact plug 138. The metal line 140 may be formed by forming a conductive metal layer with a given thickness on the entire surface of the semiconductor substrate 100 having the second contact plug 138. Forming the metal line 140 may also include forming a patterned photoresist layer on the conductive metal layer and performing a dry etch process using the photoresist layer as an etch mask. The metal line 140 may be formed to include one selected from polysilicon doped with conductive impurities, tungsten, silicide, aluminum silicide, tungsten, aluminum and/or copper and may be formed to be electrically connected to the ground end and/or back-bias end.

In the method of fabricating the phase change memory device 30 according to example embodiments, the resistance value of the lower electrode 128 may be formed more uniformly, by removing the first hard mask layer 118 used in patterning the contact pad 116, forming the third contact hole 126 in the first interlayer insulating layer on the contact pad 116 to expose the contact pad 116 and forming the lower electrode 128, electrically connected to the contact pad 116, through the third contact hole 126. The resistance value of the lower electrode 128 may have a height or thickness equal or similar to the thickness of the first interlayer insulating layer, thereby improving or maximizing a production yield.

According to example embodiments, the first hard mask layer used in patterning the contact pad may be removed and the third contact hole exposing the contact pad may be formed in the first interlayer insulating layer on the contact pad. Although the first hard mask layer is irregularly etched, the lower electrode, formed inside the third contact hole on the contact pad, may be formed to have a relatively uniform resistance value, thereby improving or maximizing a production yield.

Because the first hard mask layer formed on the contact pad is removed before the lower electrode is formed, a variance in the resistance value of the lower electrode, caused in a subsequent process due to the hard mask layer being etched at a non-uniform thickness during the formation of the contact pad, may be reduced and a production yield may be improved or maximized.

Various example embodiments have been described. However, it is to be understood that the scope is not limited to the disclosed embodiments. On the contrary, the scope of the claims is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

What is claimed is:

1. A method of fabricating a phase change memory device comprising:
forming a contact pad by using a first hard mask layer;
removing the first hard mask layer on the contact pad;
forming a lower electrode to be electrically connected to the contact pad through a third contact hole in a first interlayer insulating layer formed on the contact pad; and
forming a phase change layer and an upper electrode on the lower electrode.

2. The method according to claim 1, wherein the lower electrode has a thickness equal or similar to a thickness of the first interlayer insulating layer.

3. The method according to claim 1, wherein removing the first hard mask layer includes performing a wet etch process using an etchant having a higher etch selectivity with respect to the first hard mask layer than the contact pad.

4. The method according to claim 1, wherein forming the first contact hole includes forming a second hard mask layer on the first interlayer insulating layer formed on the contact pad, to selectively expose the first interlayer insulating layer on the contact pad and performing a dry etch process using the second hard mask layer as an etch mask.

5. The method according to claim 1, further comprising:
forming a contact plug to be electrically connected to a semiconductor substrate by a second contact hole in a second interlayer insulating layer on the semiconductor substrate;
after forming the contact pad and the first hard mask layer, electrically connecting the first hard mask layer and the contact pad to the contact plug;
forming a third interlayer insulating layer around the contact pad and the first hard mask layer;
after removing the first hard mask layer, forming a first interlayer insulating layer on the semiconductor substrate in which the contact pad is exposed and removing the first interlayer insulating layer on the contact pad, so as to form a third contact hole exposing the contact pad;
forming a metal layer on the semiconductor substrate filling the third contact hole; and
before forming a phase change layer and an upper electrode, forming the lower electrode which includes planarizing the semiconductor substrate to expose the first interlayer insulating layer.

6. The method according to claim 3, wherein forming the first hard mask layer includes forming a silicon nitride layer.

7. The method according to claim 6, wherein the etchant includes phosphoric acid having a higher etch selectivity with respect to the silicon nitride layer.

8. The method according to claim 5, wherein each of the first interlayer insulating layer, the second interlayer insulating layer and the third interlayer insulating layer includes a silicon oxide layer formed using at least one process selected from a thermal oxidation process or a chemical vapor deposition process.

9. The method according to claim 8, wherein the thermal oxidation process is at least one process selected from the group including a high temperature oxide (HTO) process, middle temperature oxide (MTO) process and middle temperature oxide nitride oxide (MTON₂O) process.

10. The method according to claim 8, wherein the chemical vapor deposition process is at least one process selected from the group including a high density plasma (HDP) process, TEOS oxide process, USG process and SOG process.

11. The method according to claim 5, wherein forming the contact plug includes connecting the contact plug to source/drain impurity regions at both sides of a gate stack of a transistor formed on the semiconductor substrate.

12. The method according to claim 5, wherein the forming of the contact plug includes:
planarizing the second interlayer insulating layer on the semiconductor substrate using a chemical mechanical polishing process;
removing the second interlayer insulating layer by performing a dry etch process using a photoresist layer or dummy hard mask layer selectively exposing the second interlayer insulating layer formed on the source/drain impurity regions as an etch mask, thereby forming the second contact hole exposing the source/drain impurity regions;
forming a conductive metal layer on the entire surface of the semiconductor substrate having the second contact hole so as to fill the second contact hole; and
planarizing the entire surface of the semiconductor substrate to expose the second interlayer insulating layer, thereby forming the contact plug to be electrically connected to the source/drain impurity regions through the second contact hole.

13. The method according to claim 5, wherein forming the contact pad and the first hard mask layer includes:
forming a conductive metal layer with a given thickness on the semiconductor substrate having the contact plug and forming the first hard mask layer selectively covering only the conductive metal layer on the contact plug; and
removing the conductive metal layer by performing a dry etch process using the first hard mask layer as an etch mask, thereby forming a contact pad.

14. The method according to claim 13, wherein the contact pad is composed of tungsten (W) or aluminum (Al) and formed using a physical deposition process or a chemical vapor deposition process.

15. The method according to claim 5, wherein forming the third interlayer insulating layer includes:
forming the third interlayer insulating layer with a given thickness on the first hard mask layer and the second interlayer insulating layer; and
planarizing the semiconductor substrate to expose the first hard mask layer.

16. The method according to claim 5, wherein forming the third contact hole includes:
stacking the first interlayer insulating layer and a second hard mask layer on the semiconductor substrate in which the contact pad is exposed; and
removing the second hard mask layer and the first interlayer insulating layer formed on the contact pad.

17. The method according to claim 16, wherein the first interlayer insulating layer and the second hard mask layer are formed in-situ inside one process chamber where a chemical vapor deposition process is performed.

18. The method according to claim 16, wherein removing the second hard mask layer includes planarizing the semiconductor substrate to expose the first interlayer insulating layer after forming the conductive metal layer filling the third contact hole during the formation of the lower electrode.

19. The method according to claim 1, wherein forming the lower electrode includes forming at least one material selected from titanium (Ti), titanium nitride (TiN) and titanium oxynitride (TiON) using a chemical vapor deposition process.

20. The method according to claim 1, wherein forming the phase change layer includes forming at least one material selected from Ge, Sb, Te, Se, Bi, Pb, Sn, As, S, Si, P, O and a mixture or alloy thereof.

21. The method according to claim 1, wherein the phase change layer is in an amorphous state at the initial deposition time and at a temperature of about 100° C. to about 300° C.

22. The method according to claim 20, wherein the upper electrode is formed at a given temperature or less so as not to change the initial state of the phase change layer.

23. A phase change memory device comprising:
a second interlayer insulating layer formed on a semiconductor substrate;
a contact plug to be electrically connected to the semiconductor substrate, through a second contact hole formed in the second interlayer insulating layer;
a contact pad formed on the contact plug;
a third interlayer insulating layer formed on the contact pad and the second interlayer insulating layer;
a lower electrode formed to be electrically connected to the contact pad through a third contact hole formed in a first interlayer insulating layer to expose the contact pad;
a phase change layer and an upper electrode stacked on the lower electrode and the third interlayer insulating layer; and
a fourth interlayer insulating layer formed on the third interlayer insulating layer around the phase change layer and the upper electrode.

24. The phase change memory device according to claim 23, wherein the lower electrode is formed with a thickness equal or similar to that of the first interlayer insulating layer.
